(19) United States
(12) Patent Application Publication
(10) Pub. No.: US 2003/0193055 A1
(43) Pub. Date: Oct. 16, 2003

(54) Lighting device and method

(76) Inventors: Robert H. Martter, Erie, PA (US); Craig C. Sundberg, Erie, PA (US); Richard N. Giardina, Erie, PA (US); Brian S. Fetscher, Girard, PA (US); G. James Deutschlander, Erie, PA (US)

Correspondence Address: RANKIN, HILL, PORTER & CLARK, LLP, 700 HUNTINGTON BUILDING, 925 EUCLID AVENUE, SUITE 700, CLEVELAND, OH, 44115-1405, US

(21) Appl. No.: 10/120,158

(22) Filed: Apr. 10, 2002

(51) Int. Cl. H01L 27/15

(52) U.S. Cl. 257/79

(57) ABSTRACT

A lighting device having a light emitting diode (LED). The device includes a metal substrate having a surface. A dielectric coating layer is superimposed on the surface of the metal substrate. A light emitting diode (LED) is supported on the dielectric coating layer. The metal substrate serves as a heat sink for the heat emitted by LED during operation.

### BACKGROUND

1. Technical Field

The present invention relates generally to a lighting device including a light emitting diode supported on an electrically insulated metal substrate.

2. Description of Prior Art

A light emitting diode (LED) includes a semiconductor chip that emits light and heat in response to the application of an electrical current. There are two major types of LEDs, “packaged” and “unpackaged.” A packaged LED is one with a solderable lead and a reflector cup. In a packaged LED, a semiconductor chip, for example an Indium Gallium Nitride (InGaN) or Indium Phosphide (InP) semiconductor chip, is housed in the reflector cup inside an optically transparent epoxy shell.

An unpackaged LED is also available. An unpackaged LED has a bare die, that is, the semiconductor chip has no solderable lead or reflective cup. Because an unpackaged LED lacks the solderable lead, an electrically conductive adhesive bonds the semiconductor chip directly to the circuit board. A wire connects the top of the semiconductor chip to circuits on the circuit board. The wire is bonded to the circuit board after the semiconductor chip is bonded to another conductive pad on the board.

Without a reflector cup, the unpackaged LED must rely on the reflectivity of the surface of the circuit board. Coatings commonly used to enhance the circuit board reflectivity can have long-term stability problems, such as diminished performance in high ultraviolet (UV) conditions, deterioration due to weathering, sensitivity to high temperatures, and age induced yellowing.

The unpackaged LED must also rely on the heat sinking ability of the circuit board and the conductive adhesives used to bond the bare semiconductor chip. Accordingly, the initial and long-term reflectivity of the board surfaces, the heat sinking ability of the circuit board material and the conductive adhesive, and the performance of the LED itself can define the LED performance level and longevity.

A particular type of LED is a High Brightness LED (HBLED). The HBLED emits an increased level of light in comparison to a conventional LED. The HBLED has a longer useful life and consumes less power than a comparable LED. Another type of LED is a semiconductor laser diode (LD).

In general, both the brightness of the light emitted and the amount of heat generated increases as more electric current is applied to the LED. The heat shedding capacity of the LED defines an upper threshold for the application of more current. Accordingly, the efficiency of the LED to shed heat limits the brightness attainable by the LED.

To increase the total light output of a lighting device, multiple LEDs or HBLEDs are combined to form an array. Such and array is called a light engine. The light engine can contain from two to several thousands of LEDs. The more LEDs used, the larger the total light output from the light engine.

Light engines are generally manufactured using a fiberglass-epoxy printed circuit board (PCB). Packaged LEDs are generally soldered onto the circuit board. To increase the brightness of the illumination, the entire circuit board mounts on a heat sink device to remove the heat generated by the operation of the LEDs. The heat sink device conducts heat away from the LEDs. This can allow more current to be applied and, thus, more light to be emitted by the LEDs.

The PCB can also include resistors. The resistors can be printed onto the PCB using organic or polymer based materials. Once on the PCB, the resistors can be trimmed by, for example, a laser. This allows the resistors to attain very precise resistance tolerances. However, the heat from the trimming operation can damage PCBs formed of traditional reinforced plastics. This susceptibility to heat damage limits the usefulness of resistor trimming in PCB applications.

### SUMMARY

The present invention provides a new and improved apparatus for use as a light emitting diode (LED) lighting device. The present invention provides a robust support for LEDs that affords excellent heat sink properties and the ability to laser trim circuitry without risk of damaging the underlying substrate. The invention may include a high temperature coating layer having controlled reflectance that offers long-term color stability and reflectivity. The apparatus includes a metal substrate having a surface with a dielectric coating layer disposed on the surface of the metal substrate. A light emitting diode (LED) is supported on the dielectric coating layer. The metal substrate serves as a heat sink for the heat emitted by the LED during operation of the device.

The present invention also provides a method for making a light emitting diode (LED) light engine. The method includes coating a metal substrate with a dielectric coating material. The method further includes mounting an LED on the coated metal substrate to form the light emitting diode (LED) light engine.

The foregoing and other features of the invention are hereinafter more fully described and particularly pointed out in the claims, the following description setting forth in detail certain illustrative embodiments of the invention, these being indicative, however, of but a few of the various ways in which the principles of the present invention may be employed.

### BRIEF DESCRIPTION OF THE DRAWINGS

FIG. 1 is a perspective schematic view of an apparatus comprising a first embodiment of the invention;

FIG. 2 is a schematic cross-sectional view taken along line 2-2 in FIG. 1;

FIG. 3 is a schematic perspective view of an apparatus comprising a second embodiment of the invention;

FIG. 4 is a schematic cross-sectional view taken along line 4-4 in FIG. 3;

FIG. 5 is a schematic cross-sectional view of part of an apparatus comprising a third embodiment of the invention;

FIG. 6 is a schematic cross-sectional view of part of an apparatus comprising a fourth embodiment of the invention; and

FIGS. 7-8 are schematic cross-sectional views of additional embodiments of the invention.

### DETAILED DESCRIPTION OF PREFERRED EMBODIMENTS

A light emitting apparatus 100 comprising a first embodiment of the invention is shown in FIG. 1. The apparatus 100 is a lighting device including light emitting diodes (LEDs) on an electrically insulated metal substrate. Specifically, the apparatus 100 is an LED light engine for use in applications such as signage and lighting displays.

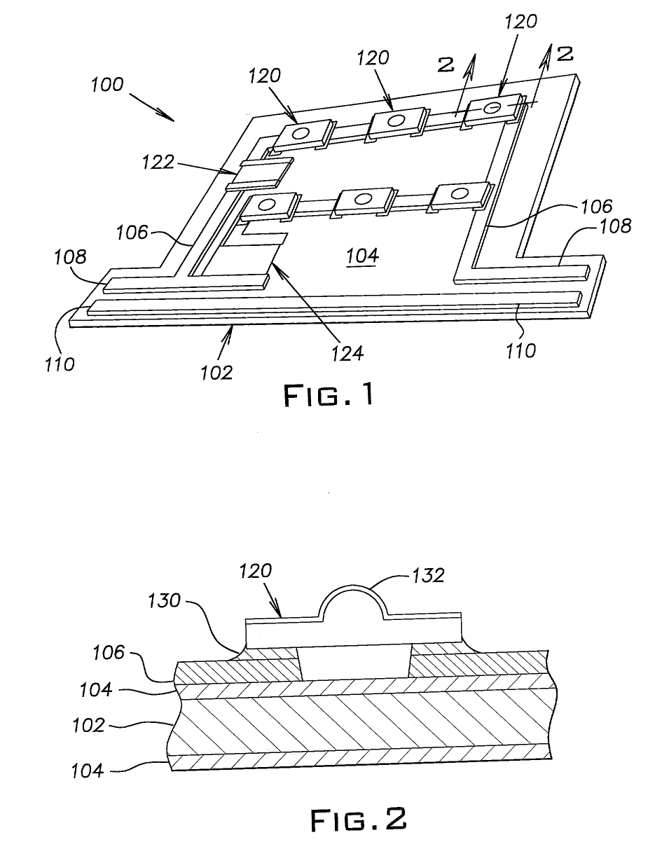

With reference to FIGS. 1-2, the apparatus 100 includes a metal substrate indicated generally by reference numeral 102. An inorganic porcelain enamel layer 104 over-coats the metal substrate 102 to form an electrically insulating dielectric layer. Electronic circuits 106 are arranged on the enamel layer 104. The electronic circuits 106 communicate first and second electronic leads 108, 110 with a plurality of light emitting diodes 120. First and second resistors 122, 124, in series with the LEDs 120, communicate with the first electronic lead 108 through the circuits 106.

In this embodiment, the metal substrate 102 is low carbon decarburized steel. The metal substrate 102 is prepared and coated with the enamel layer 104 as described in U.S. Pat. Nos. 5,605,715 and 6,195,881 assigned to The Erie Ceramic Arts Company (Erie, Pa.), which are hereby incorporated by reference in their entirety. Generally, an insulated steel substrate is formed by the process of forming a coupon of steel to the desired shape and thickness, cleaning and/or pickling the steel. The steel is then immersed in a conventional acidic copper sulphate solution after which it is dipped in a slurry of the desired coating material system such as a conventional electronic grade porcelain enamel coating slurry. During the coating process the steel is electrified such that it acts as an anode and thus attracts the solid particles in the slurry by electrophoresis. When the coated steel is removed from the slurry, it is then dried and heated to a bonding temperature of around 1500° F. in order to form the durable dielectric layer on the steel.

Metal substrates coated with a dielectric layer of electronic grade porcelain enamel are commercially available under the trade name designation ELPOR from the ECA Electronics Company (Erie, Pa.). Preferably, the dielectric layer displays a leakage current of less than 50 μAmps at 350° C.

Any number of conventional dielectric or resistive coating materials may be used in connection with the present invention. Such coatings may be classified as either “porcelain enamel,” “glass” or “ceramic” or “glass/ceramic.” Such “porcelain enamel” or “glass” coatings may be referred to as “vitreous” coatings. Such “ceramic” coatings may be referred to as “devitrified” coatings.

Other suitable metal substrates coated with a dielectric layer and their methods of production are disclosed in U.S. Pat. No. 6,195,881 issued to Giardina et al; U.S. Pat. No. 5,002,903 issued to Lim et al, U.S. Pat. No. 4,361,654 issued to Ohmura et al; U.S. Pat. No. 4,085,021 issued to Van der Vliet; U.S. Pat. No. 4,256,796 issued to Hang et al; U.S. Pat. No. 4,358,541 issued to Andrus et al.; U.S. Pat. No. 4,385,127 issued to Chyung; U.S. Pat. No. 3,841,986 issued to Gazo et al.; and U.S. Pat. No. 3,575,838 issued to Hughes, which are hereby incorporated by reference in their entirety. It will be appreciated that whatever coating material system is employed, it must afford good electrical properties and it must be competitive with commercially available thick film materials for use in forming the required circuit structure. As used herein, and the claims below, the term “insulating dielectric layer” is intended to encompass all of the above mentioned inorganic coating material systems.

The enamel layer 104 is an electronic grade porcelain enamel coating that covers the entire top surface of the metal substrate 102. Over the enamel layer 104 are the conductive circuits 106. The enamel layer 104 being disposed between the metal substrate 102 and the circuits 106, forms a dielectric layer between such substrate 102 and circuits 106.

The circuits 106 are thick film conductive circuits. Preferably, the thick film is a silver cermet thick film. The silver cermet is generally silver metal particles in a boro-silicate glass matrix. Cermet thick films of various formulations for use in the present invention are commercially available from Electro-Science Laboratories, Inc. (King of Prussia, Pa.) and the Ferro Corporation of Cleveland, Ohio. The thick film circuits 106 are applied on top of the enamel layer 104 using a conventional application technique. In this instance, the circuits 106 applied using a screen-printing technique. In other embodiments, thick film circuits may be applied using other techniques involving, for example, direct writing, spraying, dipping, spinning, brushing or doctor blades. In yet another embodiment, a thick film circuit may be formed using a gold cermet thick film that is commercially available from Electro-Science Laboratories, Inc. under the trade designation 8835.

As described above, the circuits 106 communicate the first and second leads 108, 110 with various components supported on the apparatus 100. The components include the resistors 122, 124 and the LEDs 120. The resistors 122, 124 are printed thick film resistors trimmed with lasers to attain precise resistances. Resistors may be formed using any one of a variety of cermet thick films also available from the Ferro Corporation or Electro-Science Laboratories, Inc. Laser trimming can increase uniformity of the resistors and cermet materials generally display a better service as compared to organic resistor materials employed on prior art polymeric boards. Because the enamel layer 104 is resistant to high temperatures, laser trimming of the resistors 122, 124 does not degrade the enamel layer 104 or the metal substrate 102.

The LEDs 120 are commercially available packaged high brightness LEDs (HBLEDs). A commercially available conductive epoxy adhesive forms an adhesive layer 130 to adhere the LED 120 to the circuit 106. In applications, when the LED permits, conventional solder techniques may be employed to mount the LED. The LED 120 includes a transparent plastic lens 132. The lens 132 can be a colored lens, if desired.

During operation, a forward electrical current is applied to the LEDs 120 through the circuits 106. The current is controlled by the resistors 122, 124. In response to the electrical current, the LEDs 120 switch to ON and emit light and heat.

The surface of the enamel layer 104 reflects the emitted LED light away from the surface. The metal substrate 102 serves as a heat sink and thus it conducts away the heat generated by the operating LEDs 120.

It will be appreciated that portions of the circuit 106 may be coated with an encapsulated layer. A suitable encapsulant layer may be formed using a glass encapsulant sold by the Ferro Corporation of Cleveland, Ohio, under the trade designation A-3565. The glass encapsulant serves to prevent particulate migration between individual circuit traces. The encapsulant may be applied, for example, by screen printing directly on the thick film materials and the top surfaces of the dielectric layer and then the entire board may be fired at a temperature of about 625° C.

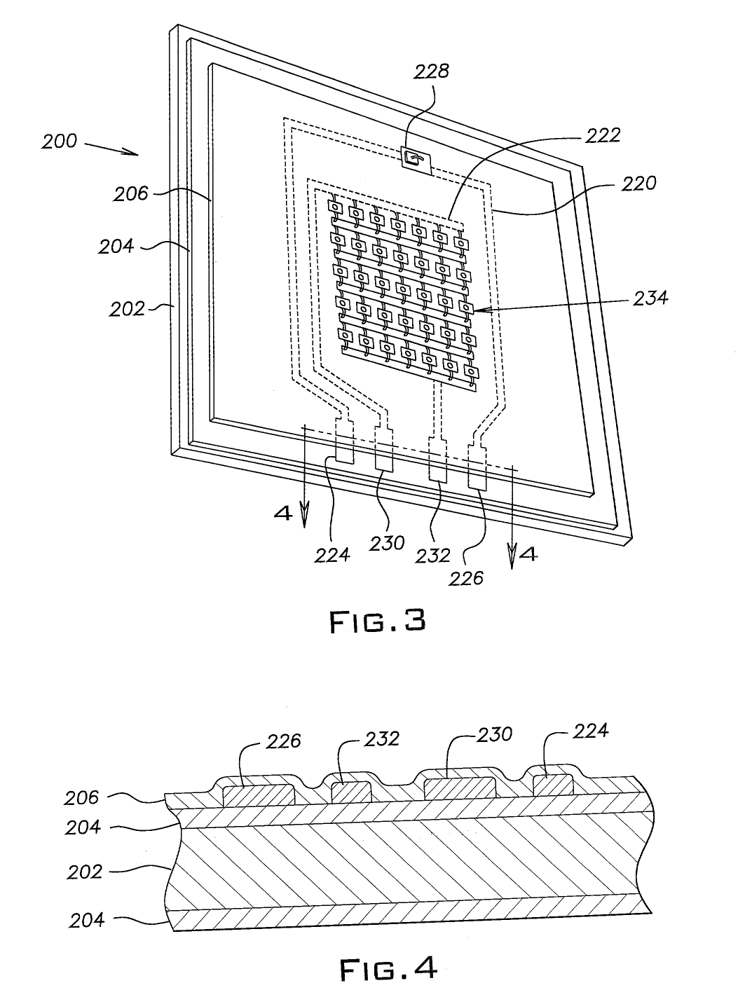

With reference to FIG. 3, an apparatus 200 comprising a second embodiment of the invention is shown. The apparatus 200 is an LED light engine similar to the light engine of the apparatus 100. The light engine 200 includes a metal substrate 202 comprising decarburized low carbon steel.

A porcelain enamel coating 204 forms a dielectric layer over the surface of the metal substrate 202. A reflective inorganic enamel coating 206 forms a white reflective layer superimposed over the enamel coating layer 205. In applications where the reflectivity of light is desired, a white coating is employed. Preferably, the white coating displays a reflectivity of at least 80%. Various white enamel coating material systems are commercially available from companies such as the Ferro Glass & Color Corporation of Washington, Pa. Applicants believe that an enamel having high reflectivity is best achieved by the formulation of a ball milled enamel powder comprising by weight 1000 parts 14390 glass frit available from Chi-Vit of Urbana, Ohio, 60 parts anatase titanium dioxide, 15 parts syloid colloidal silica available from W. R. Grace, 13 parts cerium oxide, 1.3 parts potassium nitrate, 0.6 parts potassium chloride and 3.8 parts 5500 colloidal alumina available from the Ferro Corporation. The powder is then mixed with a suitable carrier such as pine oil to facilitate screen printing or other application techniques. The enamel layer may be applied using conventional techniques upon the dielectric layer during the application of the circuit traces, and fired along with the circuit trace materials.

First and second thick film circuits 220, 222 are formed on the enamel coating 204 using methods known to one skilled in the art. First and second electrical leads 224, 226 communicate with a thermal sensor (thermistor) 228 through the first circuit 220. Third and fourth electrical leads 230, 232 communicate with an of unpackaged or bare die array of LEDs 234 through the second circuit 222.

The first and second circuits 220, 222 are in part disposed between the enamel coating 204 and the reflective coating 206. The reflective coating 206 is arranged over the first and second circuits 220, 222,but under the array 234 and the thermal sensor 228. However, the electrical leads 224, 226, 232, 234 each have portions that are not covered by the reflective coating 206. The reflective coating 206 is positioned both to reflect a portion of the emitted light from the array 234 away from the light engine 200, and to allow electrical contact with portions of the electrical leads 224, 226, 232, 234.

With reference to FIG. 4, a cross sectional view of a portion of the light engine 200 is shown. The ceramic coating layer 204 is disposed between the electrical leads 224, 226, 232, 234 and the metal substrate 202. In contrast, the reflective coating 206 covers portions of the electrical leads 224, 226, 232, 234 but is not located between the electrical leads 224, 226, 232, 234 and the metal substrate 202.

During operation, a forward electrical current is applied to the leads 224, 226, 232, 234 and through the first circuit 220 to the thermal sensor 228, and through the second circuit 222 to the array of LEDs 234.

In response to the electrical current, the array of LEDs 234 emit light and heat. The reflective coating 206 reflects light away from its surface and the metal substrate 202 conducts away heat generated by the operating array of LEDs 234.

The thermal sensor 228 senses the temperature of the substrate 202 and the ambient air. The sensor 228 then signals a controller (not shown) that can adjust the current application to the array of LEDs 234 in response to the signal.

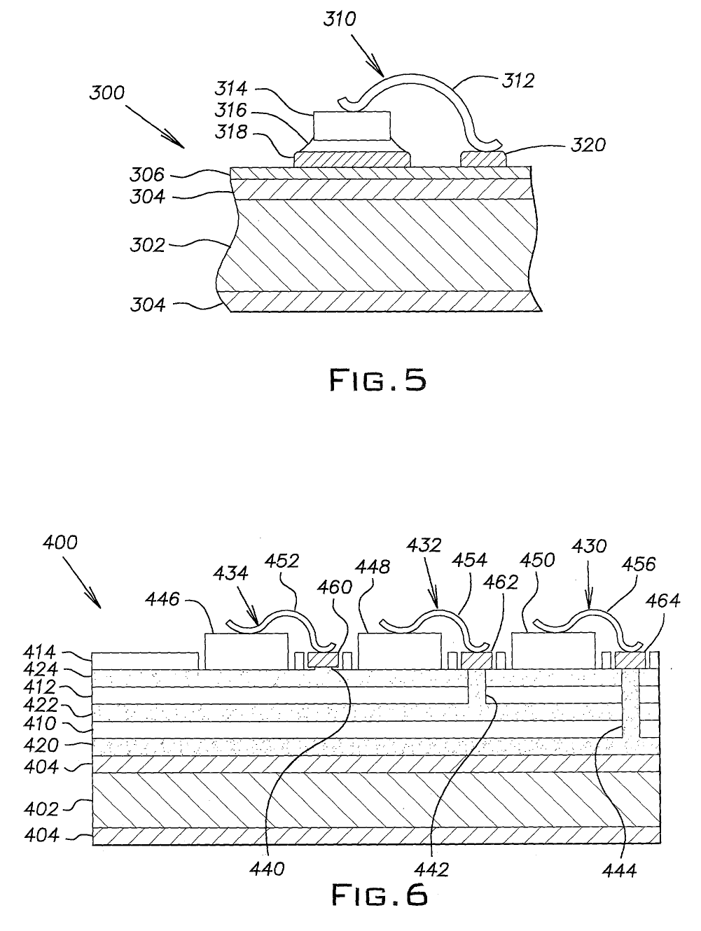

In FIG. 5, an apparatus 300 comprising a third embodiment of the invention is shown. The apparatus 300 includes a decarburized steel substrate 302. An electrically insulative dielectric layer 304 coats the metal substrate 302. Superimposed on a portion of the coating layer 304 is an inorganic white layer 306. However, it will be appreciated that any number of colored (controlled reflectance) enamels, such as black enamel, may be employed depending upon the desired reflectivity properties. High temperature enamels in various colors are available from the Ferro Corporation.

A plurality of unpackaged LEDs each include a gold wire 310 and an InGaN semiconductor chip 314. The chip 314 is adhered by an adhesive layer 316 to a first thick film, conductive printed circuit 318. The wire communicates with a second thick film, conductive printed circuit 320.

During operation, a negative (−) electrical potential is applied to the first circuit 318 and a positive (+) electric potential is applied to the second circuit 320. The chip 314 communicates with the first and second circuits 318, 320 through the conductive adhesive 316 and through the wire 312, respectively. The chip 314 responds to the application of the electric potential by emitting light and heat. The white layer 306 reflects the light contacting the white layer 306. The metal substrate 302 conducts heat away from the chip 314.

With reference to FIG. 6, a cross-sectional view of part of an apparatus 400 comprising a fourth embodiment of the invention is shown. The apparatus 400 is a light engine including a stainless steel substrate 402. The stainless steel substrate 402 is overcoated with an electronic grade porcelain enamel coating layer 404.

Superimposed over the coating layer 404 is a plurality of dielectric coating layers. Specifically, first, second and third layers 410, 412, 414 of dielectric material cover a portion of the surface of the coating layer 404. Separated from each other by interspersion between the dielectric layers are a plurality of thick film conductors. Specifically, first, second and third conductors 420, 422, 424 are separated from each other by the first, second and third dielectric layers 410, 412, 414, respectively.

Dielectric layers 410, 412 and 414 are produced by forming a dielectric coating using multiple discrete homogeneous layers of commercially available thick film dielectric materials intended for use on metal substrates. Examples of such materials include a thick film material available from Electro-Science Laboratories, Inc. of King of Prussia, Pa., under the trade designation 4924, thick film materials available from DuPont of Wilmington, Del., under the trade designation 3500N and thick film materials available from Heraeus of West Conshohocken, Pa., under the trade designation IP-222. These materials are intended for use in making thick film heaters, but applicants have unexpectedly found them suitable for use in the present invention.

The thick film dielectric materials are applied in multiple layers upon the enamel layer 404 and then they are fired at a temperature of about 850° C. The layers are preferably applied by screen printing and have a thickness of about 0.006″ after firing. However, other application techniques such as spraying could be utilized. Each applied layer is dried prior to application of the subsequent layer. It will be appreciated that dielectric layers 410, 412 and 414 may be formed directly upon the stainless steel substrate 402. Prior to application of the dielectric materials the stainless steel surface is thoroughly cleaned, and preferably the stainless grade employed is grade 430.

A plurality of unpackaged LEDs are supported on the apparatus 400. A first LED 430 communicates with the first conductor 420, a second LED 432 communicates with the second conductor 422, and a third LED 434 communicates with the third conductor 424. Specifically, the LEDs 430, 432, 434 each communicate with the conductors 420, 422, 424 through conductive structures called vias 440, 442, 444, respectively. The LEDs 430, 432, 434 include semiconductor chips 446, 448, 450 that communicate through conductive wire leads 452, 454, 456 with thick film resistor circuits 460, 462, 464, respectively.

The LEDs 430, 432, 434 are different colors from each other. Specifically, the LED 430 emits a red light, the LED 432 emits a blue light, and the LED 434 emits a yellow light in response to an application of an electric current.

During operation, an electric current is applied to the circuits 460, 462, 464. In response to the electric current, the LEDs 430, 432, 434 emit light and heat. Because the circuits 460, 462, 464 are electrically independent of each other, the application of the electric current can be separately controlled to each of the LEDs 430, 432, 434. Accordingly, the LEDs 430, 432, 434 can be separately controlled to switch ON and OFF.

When the LEDs 430, 432, 434 are switched ON, the heat that they generate is conducted away through the stainless steel substrate 402.

It will be appreciated that multilayer structures may also be formed by taking a porcelain enamel metal coated substrate available from ECA Electronics Company under the trade designation ELPOR and coating it with a high performance electronic grade porcelain enamel coating material available from the Ferro Corporation of Cleveland, Ohio, under the trade designation QP-330. The ECA substrate with its enamel coating provides a bottom or first dielectric layer, and the QP-330 provides top second layer. QP-330 may be applied wet to the ECA porcelain coated substrates and then fired at about 800° C. The QP-330 material may either be applied by dipping or screen printing to a thickness of about 0.002″ (after firing). One or more layers of the QP-330 material may be applied successfully to the ECA porcelain coated substrates.

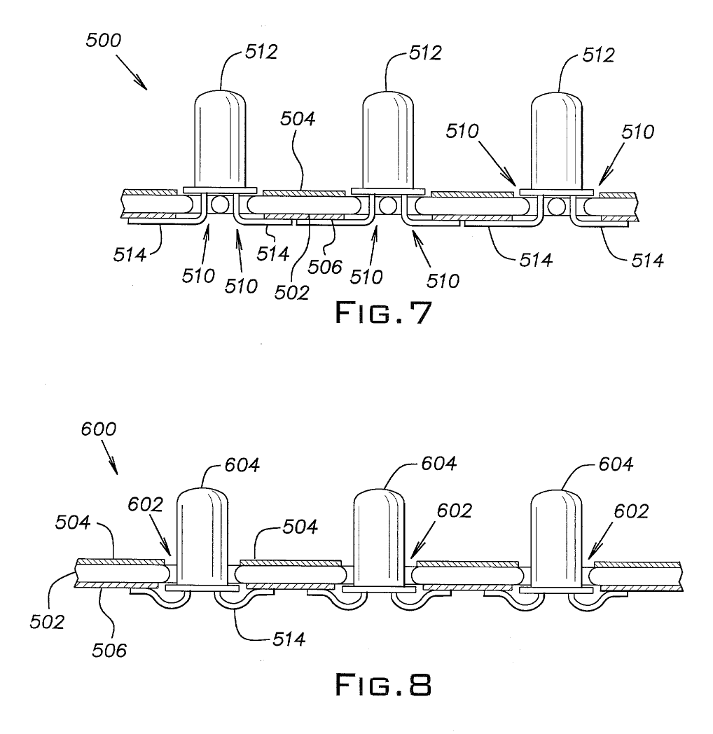

With reference to FIG. 7, an apparatus 500 comprising a fifth embodiment of the invention is shown. The apparatus 500 is a metal core circuit board supporting LEDs. The apparatus 500 includes a decarburized steel substrate 502. A reflective coating 504 is superimposed on an upper surface of the substrate 502 and a conductive thick film circuit pattern 506 is superimposed on a lower surface of the substrate 502.

An array of apertures 510 extends from the upper side to the lower side through the substrate 502. The array 510 is arranged such that pairs of closely spaced apertures are spaced apart from other pairs of closely spaced apertures.

Mounted on the upper side of the substrate 502 is a plurality of leaded or line-terminated, packaged LEDs 512. The LEDs 512 each have a pair of solderable leads 514 that extend through one of the pairs of closely spaced apertures. The leads 514 are soldered to the circuit pattern 506 on the under side of the substrate 502 to secure the LEDs 512 to the upper side of the substrate 502.

FIG. 8 shows an apparatus 600 comprising another embodiment of the invention. The apparatus 600 includes many parts that are substantially the same as parts of the apparatus 500; this is indicated by the use of the same reference numerals in FIGS. 7 and 8. The apparatus 600 differs from the apparatus 500 in that the apparatus 600 includes an array of apertures 602 sized and shaped to accommodate the insertion of a corresponding plurality of packaged LEDs 604.

The LEDs 604 are mounted to the lower side of the substrate 502, but partially extend through the array of apertures 602 to the upper side. The leads 514 are soldered or bonded with a conductive epoxy to the circuit pattern 506 to secure the LEDs 604 to the substrate 502.

During operation, an electric current is applied to the circuit pattern 506 and subsequently to the leads 514. In response to the electric current, the LEDs 512, 604 emit light and heat. Heat is conducted away from the LEDs 512, 514 by the substrate 502.

Also envisioned are alternative embodiments which have substrates comprising metals that differ from the metals disclosed above. Such substrates may comprise, for example, a ferrous alloy such as a carbon-steel or another metal, such as copper, aluminum and copper-beryllium.

The embodiments described herein are examples of structures having elements corresponding to the elements of the invention recited in the claims. This written description may enable those skilled in the art to make and use embodiments having alternative elements that likewise correspond to the elements of the invention recited in the claims. The intended scope of the invention thus includes other structures that do not differ from the literal language of the claims, and further includes other structures, systems or methods with insubstantial differences from the literal language of the claims.

What is claimed is:

1. An apparatus for use as a light emitting diode (LED) lighting device, comprising:
a metal substrate having a surface;
a dielectric coating layer superimposed on the surface of the metal substrate;
an electric circuit disposed upon the coating layer; and
a light emitting diode (LED) mounted upon the substrate and electrically connected to the circuit, whereby the metal substrate serves as a heat sink for the LED.

2. The apparatus as defined in claim 1, wherein the metal substrate comprises a metal selected from the group consisting of copper, steel, aluminum, and alloys thereof.

3. The apparatus as defined in claim 1, wherein the dielectric coating layer comprises an electronic grade inorganic material selected from the group consisting of ceramic materials, porcelain enamel materials, and glass materials.

4. The apparatus as defined in claim 1, wherein the LED is a packaged LED.

5. The apparatus as defined in claim 1, wherein the LED is a line terminated LED.

6. The apparatus as defined in claim 1, wherein said circuit comprises a cermet metal circuit communicating with the LED.

7. The apparatus as defined in claim 1, wherein said circuit includes one or more resistors.

8. The apparatus as defined in claim 7, wherein the resistors are laser trimmed resistors.

9. The apparatus as defined in claim 1, further comprising a conductive coating layer superimposed on the dielectric coating layer and an additional dielectric coating layer superimposed on the conductive coating layer, whereby a portion of the conductive layer is sandwiched between the dielectric coating layer and the additional dielectric coating layer.

10. The apparatus as defined in claim 1, further comprising a reflective coating layer superimposed on the dielectric coating layer.

11. The apparatus as defined in claim 1, further comprising a white reflective coating layer superimposed on the dielectric coating layer.

12. The apparatus as defined in claim 1, further comprising a light absorbing black inorganic coating layer superimposed on the dielectric coating layer.

13. The apparatus as defined in claim 1, wherein the LED includes an electrical lead and the metal substrate has an aperture, the LED has a portion that extends through the aperture in the metal substrate.

14. The apparatus as defined in claim 13, wherein the electrical lead is soldered or bent over, thereby supporting the LED on the metal substrate.

15. A method for making a light emitting diode (LED) light engine, comprising:
coating a metal substrate with a dielectric coating material; and
mounting an LED on the coated metal substrate to thereby form the light emitting diode (LED) light engine, whereby the metal substrate is a heat sink for the LED.

16. The method as defined in claim 15, further comprising adding circuitry to the metal substrate and laser trimming the circuitry.

17. The light emitting diode (LED) light engine made by the method of claim 15.

18. An apparatus for use as a light emitting diode (LED) light engine, comprising:
means for coating a metal substrate with a dielectric coating material; and
means for mounting an LED on the coated metal substrate to thereby form the light emitting diode (LED) light engine, whereby the metal substrate is a heat sink for the LED.
